(19) United States
(12) Patent Application Publication
(10) Pub. No.: US 2025/0287678 A1
(43) Pub. Date: Sep. 11, 2025

(54) MANUFACTURING METHOD OF SEMICONDUCTOR INTEGRATED STRUCTURE HAVING HIGH/LOW VOLTAGE DEVICES AND CAPACITOR

(71) Applicant: Richtek Technology Corporation, Zhubei City (TW)

(72) Inventors: Yu-Wei Hsu, Tainan (TW); Han-Chung Tai, Hsinchu (TW); Chun-Lung Chang, Hsinchu (TW)

(21) Appl. No.: 18/666,904

(22) Filed: May 17, 2024

(30) Foreign Application Priority Data
Mar. 8, 2024 (TW) 113108618

(51) Int. Cl. H01L 21/8234; H01L 21/265

(52) U.S. Cl. CPC H10D 84/038; H01L 21/2652; H10D 1/68; H10D 84/0142; H10D 84/0144; H10D 84/0156

(57) ABSTRACT

A manufacturing method of a semiconductor integrated structure having a high voltage device, a low voltage device and a capacitor, includes: forming a bottom thermal oxide layer on a substrate; forming a chemical vapor deposition (CVD) oxide layer; forming a poly silicon hard mask layer; etching the poly silicon hard mask layer to form a high voltage poly silicon hard mask and a first electrode plate simultaneously; etching the CVD oxide layer and using the high voltage poly silicon hard mask and the first electrode plate as etching barrier layers to form a high voltage CVD oxide region and a capacitor CVD oxide region simultaneously; etching the bottom thermal oxide layer and using the high voltage poly silicon hard mask and the first electrode plate as the etching barrier layers to form a high voltage bottom thermal oxide region and a bottom thermal oxide region simultaneously.

### CROSS REFERENCE

The present invention claims priority to TW 113108618 filed on Mar. 8, 2024.

### BACKGROUND OF THE INVENTION

### Field of Invention

The present invention relates to a manufacturing method of a semiconductor integrated structure having high and low voltage devices and a capacitor, particularly, it relates to such semiconductor integrated structure which integrates a high voltage device, a low voltage device, and a poly silicon-insulator-poly silicon (PIP) capacitor.

### Description of Related Art

Referring to FIG. 1, which shows a sectional schematic view of a prior art semiconductor integrated structure 10 comprising a high device HV1, a low voltage device LV1 and a capacitor (not shown). As illustrated in FIG. 1, the semiconductor integrated structure 10 is formed on a substrate 11, comprising plural insulation regions 12, a low voltage gate 13a, a high voltage gate 13b, a low voltage source 14a, a high voltage source 14b, a low voltage drain 15a, a high voltage drain 15b, a reduce surface electric field (RESURF) oxide region 16, and a body region 17.

The plural insulation regions 12 serve to electrically isolate the low voltage device LV1 from the high voltage device HV1 in the substrate 11. The low voltage gate 13a is formed on the substrate 11 of the low voltage device LV1, with the low voltage source 14a and the low voltage drain 15a also formed in the substrate 11. Meanwhile, the high voltage gate 13b and the RESURF oxide region 16 are formed on the substrate 11 of the high voltage device HV1, with the high voltage source 14b and the high voltage drain 15b also formed in the same substrate 11.

In a typical LDMOS device, as the high voltage device HV1 shown in FIG. 1, employing a field plate structure (the RESURF oxide region 16 and an extension of the high voltage gate 13b) is the most effective method to improve device breakdown voltage and to mitigate issues of hot carrier injection near the gate edge. This approach alleviates localized electric field crowding that could lead to early device failure. Although a traditional LOCOS field oxide region, as illustrated for the RESURF oxide region 16 in FIG. 1, is the simplest way to implement a field plate structure without additional mask definitions, they can cause severe issues such as increased on-resistance during high-temperature annealing processes or boron diffusion outward from LDMOS devices.

To resolve these issues, a field plate composed of a dielectric layer with an angled profile relative to the surface of the substrate 11, typically made of silicon dioxide, but also potentially of silicon nitride, silicon oxynitride, or high-k materials, is used between the high voltage gate 13b and the substrate 11 to implement the RESURF technique.

However, this angled dielectric layer structure might involve additional oxide growth thermal processes that lead to exceeding the thermal budget; furthermore, defining this angled dielectric layer can result in shallow trench isolation (STI) corner loss, also known as notching, due to additional wet etching processes. Consequently, prior art has introduced a novel two-step angled dielectric layer oxidation process and a maskless poly silicon-insulator-poly silicon (PIP) capacitor structure to overcome these challenges.

Additionally, the prior art encounters challenges with photoresist stripping during wet etching steps, which can further damage the shallow trench isolation or LOCOS field oxide regions; additionally, multiple thermal oxidation processes also tend to exceed the thermal budget constraints.

In view of the above, the present invention proposes a manufacturing method of a semiconductor integrated structure having high and low voltage devices and a capacitor, which avoids damage to the shallow trench isolation or LOCOS field oxide regions and reduces the number of thermal oxidation processes, thus addressing problems related to notching and exceeding thermal budget limitations.

### SUMMARY OF THE INVENTION

From one perspective, the present invention provides a manufacturing method of integrated an structure of a semiconductor integrated structure having high and low voltage devices and a capacitor, comprising: forming a bottom thermal oxide layer on a substrate, wherein the bottom thermal oxide layer completely covers a high voltage device area, a low voltage device area, and a capacitor area of the substrate; forming a high voltage well in the substrate of the high voltage device area; forming a chemical vapor deposition (CVD) oxide layer that completely covers the bottom thermal oxide layer; forming a polysilicon hard mask layer that completely covers the CVD oxide layer; etching the polysilicon hard mask layer to simultaneously form a high voltage polysilicon hard mask in the high voltage device area and a first electrode plate in the capacitor area; etching the CVD oxide layer using the high voltage polysilicon hard mask and the first electrode plate as etching barriers to simultaneously form a high voltage CVD oxide region in the high voltage device area and a capacitor CVD oxide region in the capacitor area; forming a low voltage well in the substrate of the low voltage device area; etching the bottom thermal oxide layer using the high voltage polysilicon hard mask and the first electrode plate as etching barriers to simultaneously form a high voltage bottom thermal oxide region in the high voltage device area and a bottom thermal oxide region in the capacitor area; forming a high voltage gate oxide layer over the high voltage device area on the substrate; forming a low voltage gate oxide layer over the low voltage device area on the substrate; when forming the high voltage gate oxide layer or the low voltage gate oxide layer, simultaneously forming a capacitor dielectric layer, connected and fully covering the first electrode plate; forming a gate polysilicon layer, connected and fully covering the high voltage gate oxide layer, the low voltage gate oxide layer, and the capacitor dielectric layer; and etching the gate polysilicon layer to simultaneously form a high voltage gate in the high voltage device area, a low voltage gate in the low voltage device area, and a second electrode plate in the capacitor area.

In one embodiment, the step of forming the low voltage well in the substrate of the low voltage device area includes: using an ion implantation process step, with the bottom thermal oxide layer serving as a sacrificial layer, and accelerating ions to penetrate the sacrificial layer to implant into the low voltage device area to form the low voltage well.

In one embodiment, the step of etching the CVD oxide layer using the high voltage polysilicon hard mask and the first electrode plate as etching barriers to simultaneously form the high voltage CVD oxide region in the high voltage device area and the capacitor CVD oxide region in the capacitor area includes: using a wet etching process step to etch the CVD oxide layer.

In one embodiment, the step of etching the bottom thermal oxide layer using the high voltage polysilicon hard mask and the first electrode plate as etching barriers to simultaneously form the high voltage bottom thermal oxide region in the high voltage device area and the bottom thermal oxide region in the capacitor area includes: using a wet etching process step to etch the bottom thermal oxide layer, such that the high voltage side wall of the high voltage bottom thermal oxide region and the capacitor side wall of the bottom thermal oxide region each have an inclined angle with respect to the upper surface of the substrate.

In one embodiment, the manufacturing method further includes: after forming the polysilicon hard mask layer, using an ion implantation process step to accelerate N-type or P-type ions to implant into the polysilicon hard mask layer.

In one embodiment, the manufacturing method further includes: after forming the gate polysilicon layer, using an ion implantation process step to accelerate N-type or P-type ions to implant into the gate polysilicon layer.

In one embodiment, the high voltage gate is in direct contact with the high voltage polysilicon hard mask.

In one embodiment, the manufacturing method further includes: after forming the high voltage gate, the low voltage gate, and the second electrode plate, forming two high voltage spacers corresponding to and connected on either side of the high voltage gate, and two low voltage spacers corresponding to and connected on either side of the low voltage gate.

In one embodiment, the manufacturing method further includes: after forming the high voltage gate, the low voltage gate, and the second electrode plate, forming two capacitor spacers corresponding to and connected on either side of the second electrode plate.

In one embodiment, the manufacturing method further includes: simultaneously forming a high voltage source and a high voltage drain in the high voltage device area, and a low voltage source and a low voltage drain in the low voltage device area.

In one embodiment, the manufacturing method further includes: using a silicidation metal process step to simultaneously form a plurality of silicide metal layers corresponding to the upper surfaces of the high voltage gate, the high voltage source, the high voltage drain, the low voltage gate, the low voltage source, the low voltage drain, the first electrode plate, and the second electrode plate.

In one embodiment, the manufacturing method further includes: forming an inter-layer dielectric (ILD) layer on the substrate, completely covering the high voltage gate, the low voltage gate, and the second electrode plate.

In one embodiment, the manufacturing method further includes: forming a plurality of electrical contact plugs in the ILD layer, electrically connecting the multiple silicide metal layers.

In one embodiment, the manufacturing method further includes: forming a high voltage body region in the high voltage well of the high voltage device area, wherein the high voltage source is located in the high voltage body region.

The objectives, technical details, features, and effects of the present invention will be better understood with regard to the detailed description of the embodiments below, with reference to the attached drawings.

### BRIEF DESCRIPTION OF THE DRAWINGS

FIG. 1 is a schematic cross-sectional view illustrating an semiconductor integrated structure 10 comprising a high device HV1, a low voltage device LV1 and a capacitor.

FIGS. 2A-2Q are schematic cross-sectional views illustrating a manufacturing method of a semiconductor integrated structure 20 having high and low voltage devices and a capacitor according to an embodiment of the present invention.

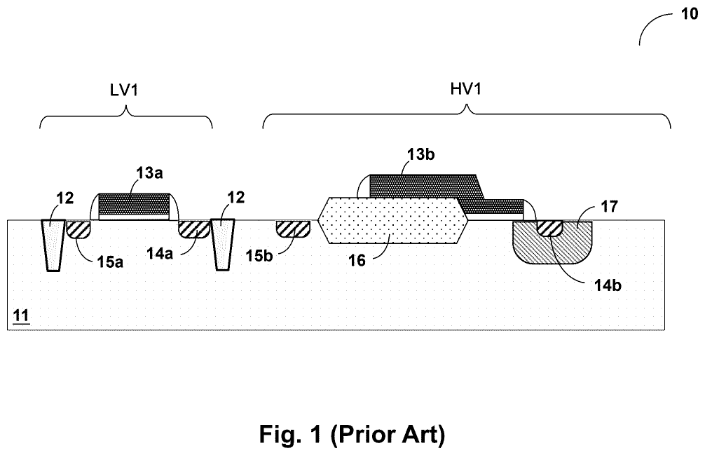

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

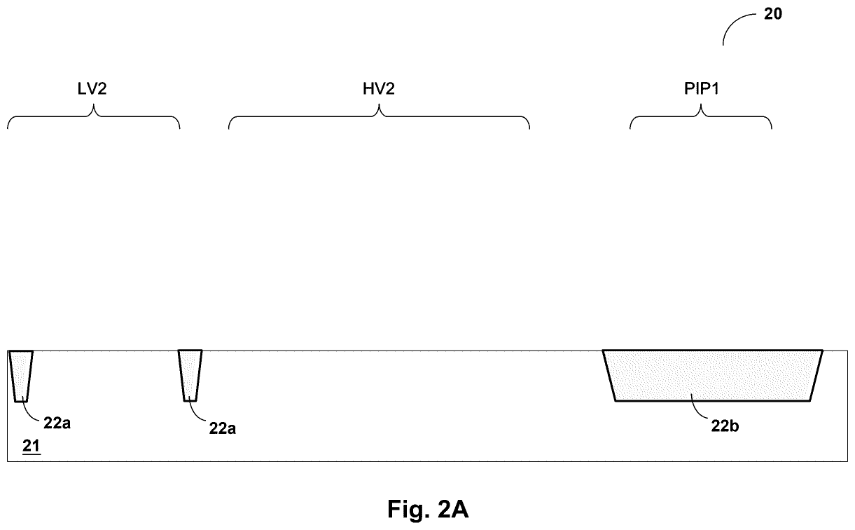

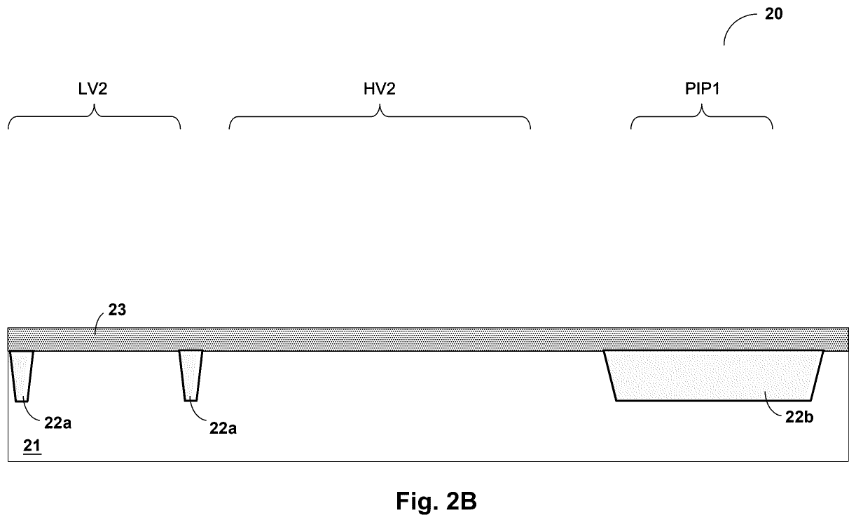

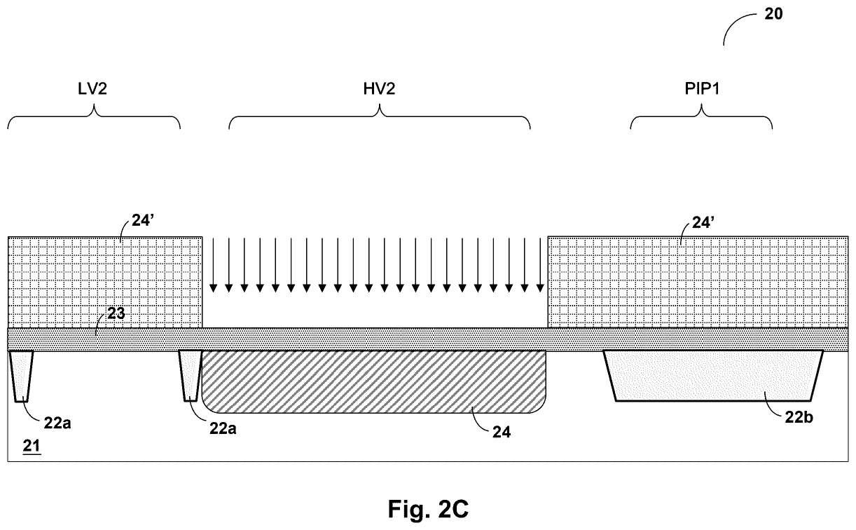

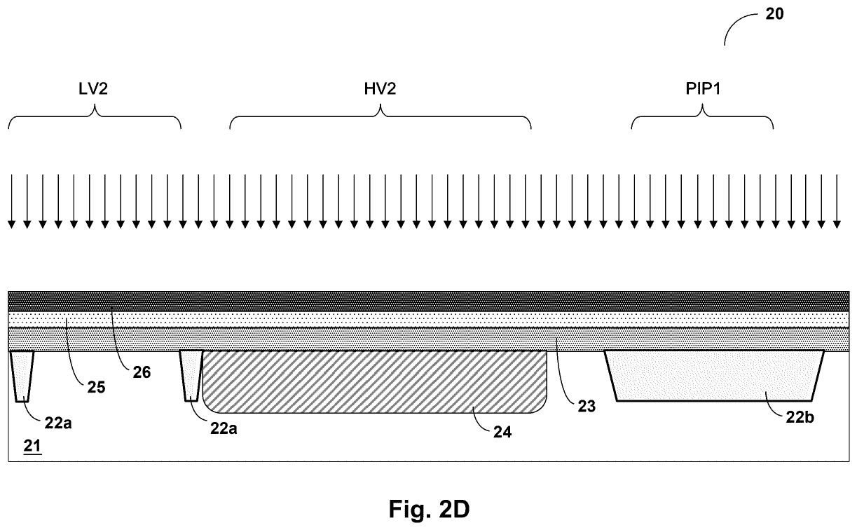

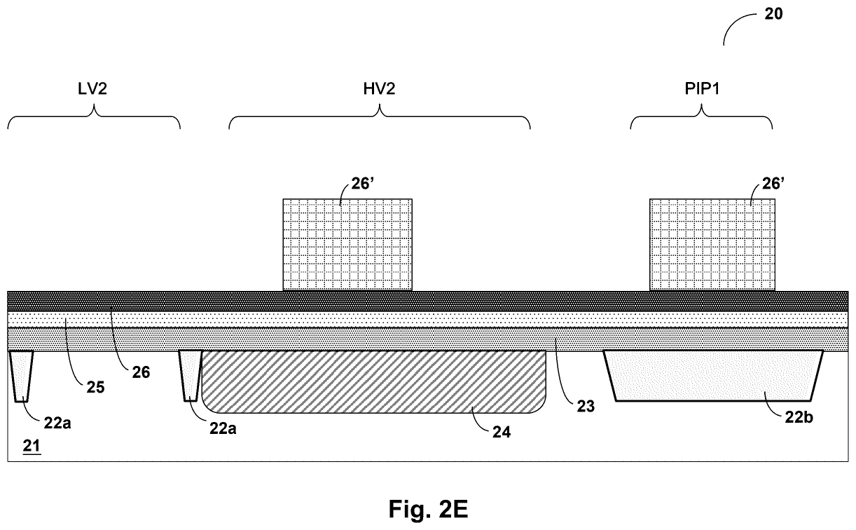

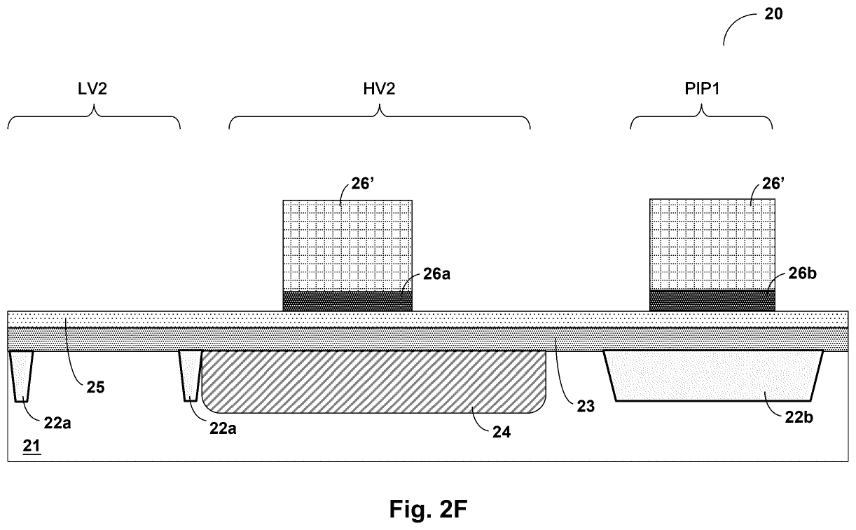

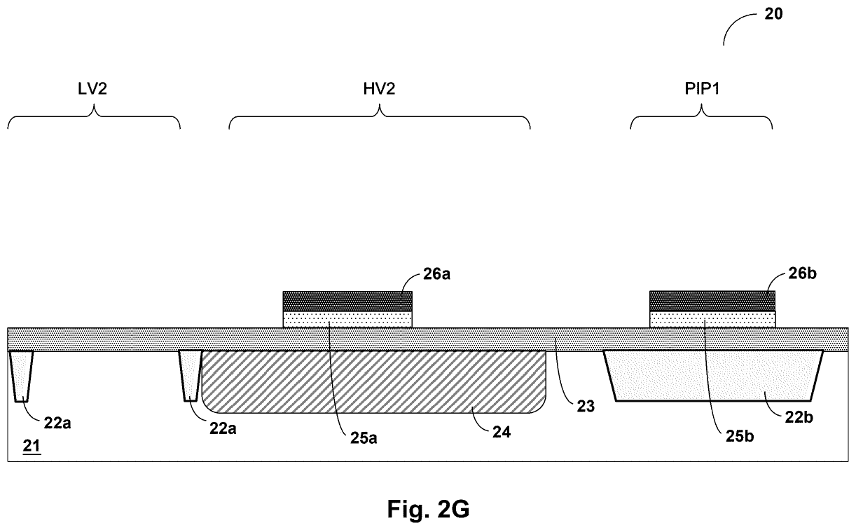

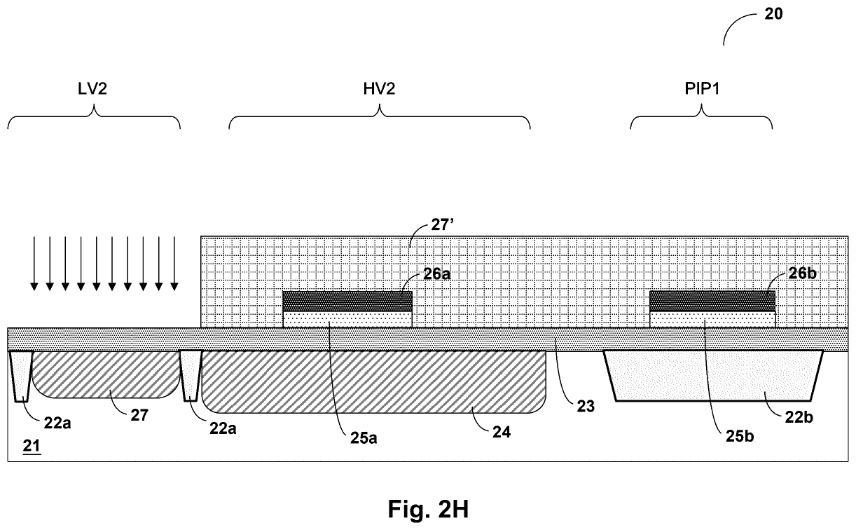

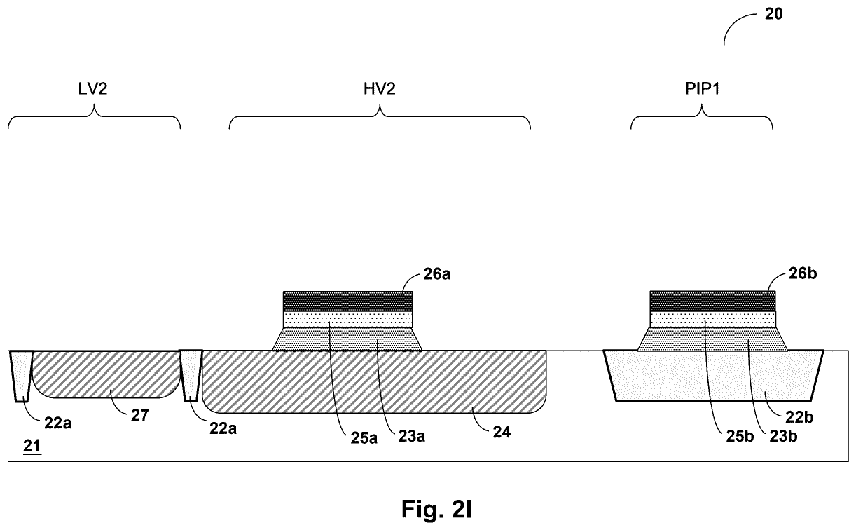

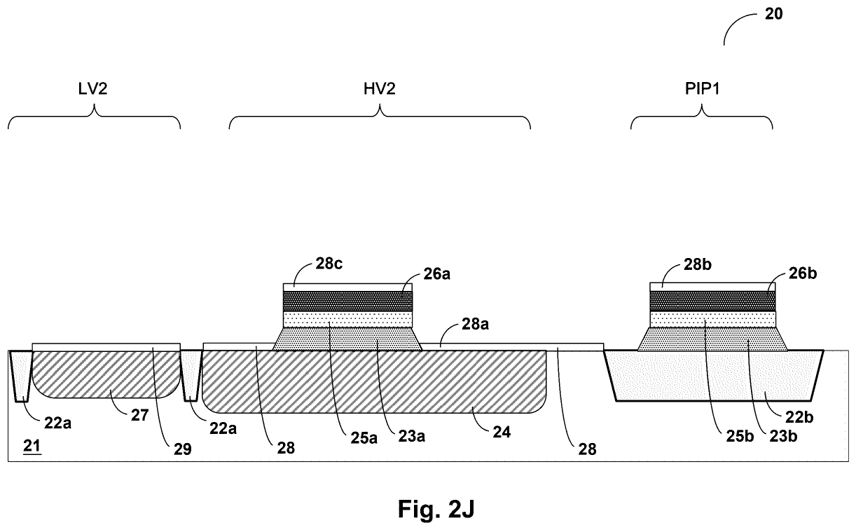

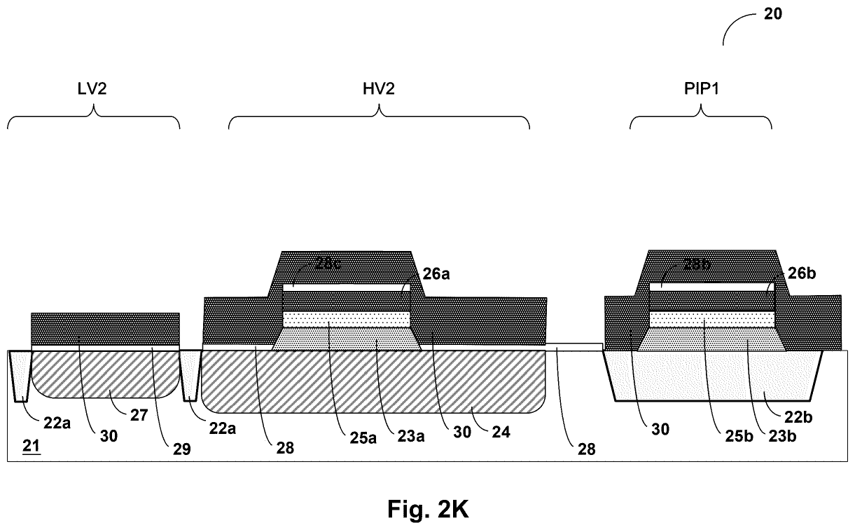

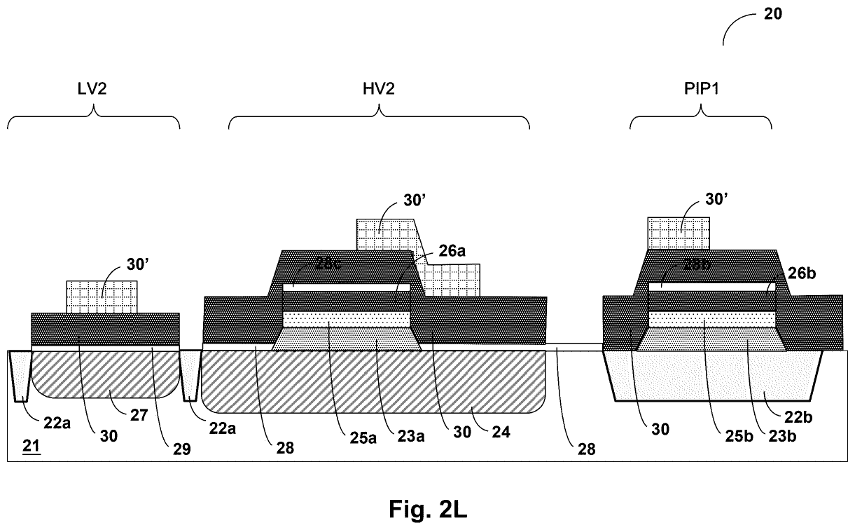

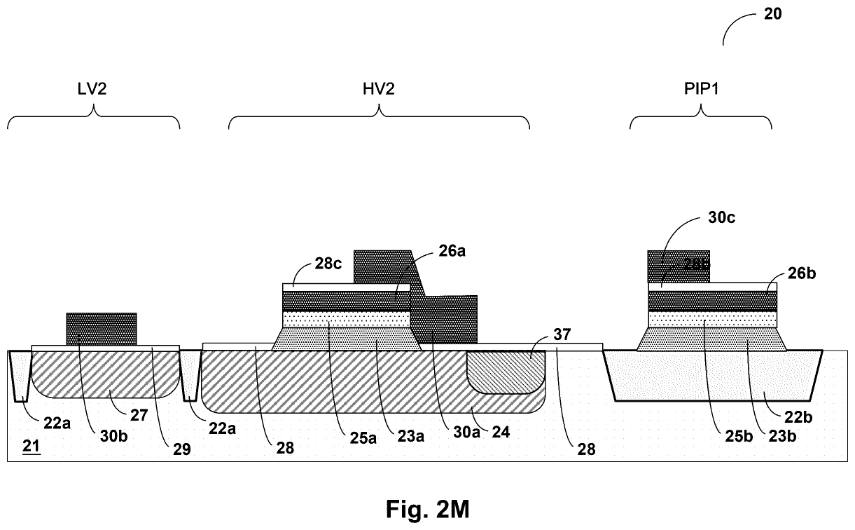

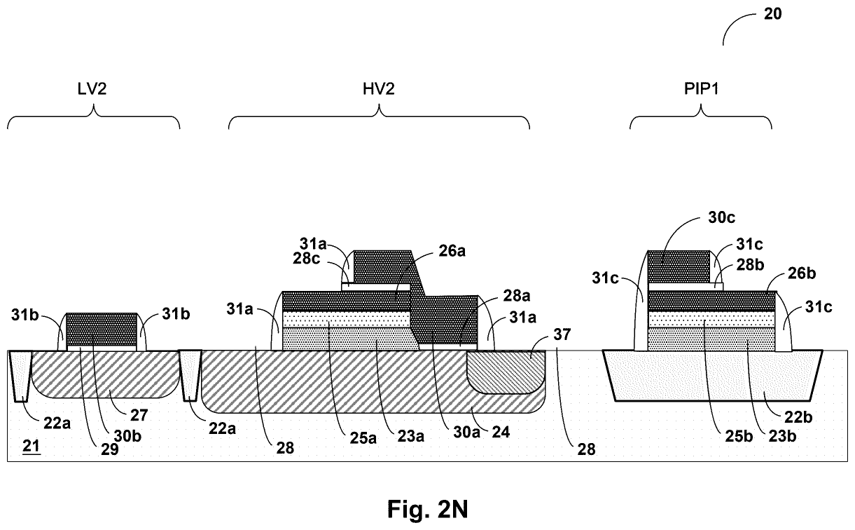

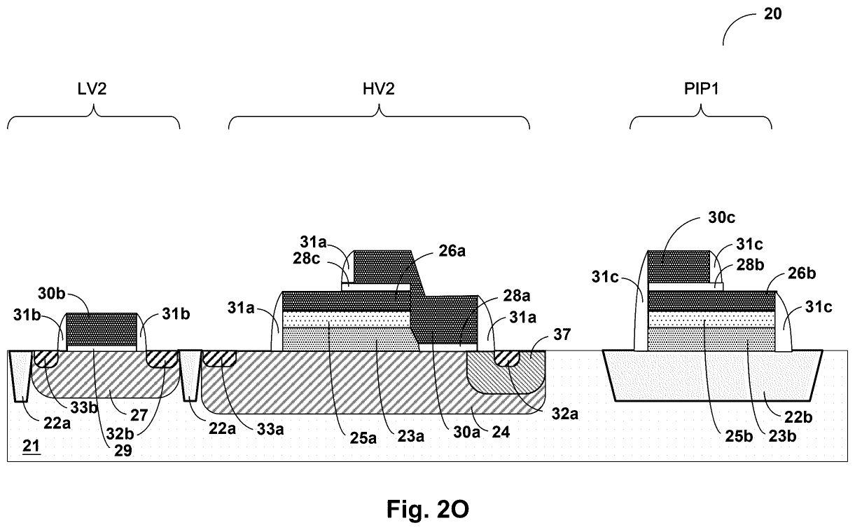

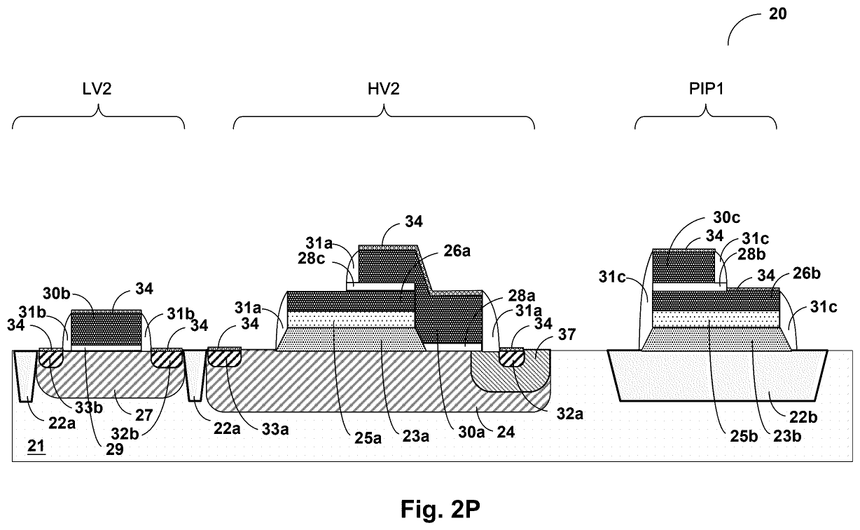

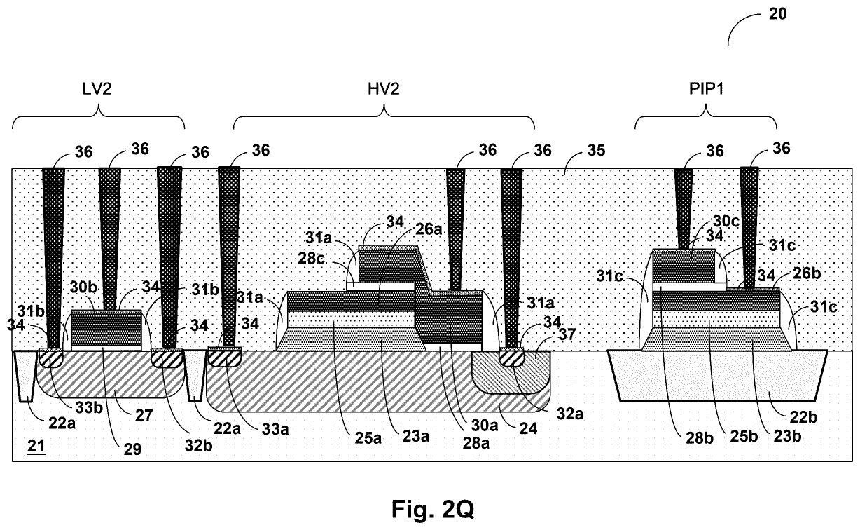

Referring to FIGS. 2A-2Q, according to an embodiment of the present invention, a cross-sectional schematic view of a method for manufacturing a semiconductor integrated structure 20 having high and low voltage devices and a capacitor is shown. As illustrated in FIG. 2A, a substrate 21 is first provided, and insulation regions 22a and 22b are formed on the substrate 21. The substrate 21 may be, for example but not limited to, a P-type or N-type semiconductor substrate. This is well known to those of ordinary skill in the art and is not further elaborated here. As shown in FIG. 2B, a bottom thermal oxide layer 23 is then formed on substrate 21, where the bottom thermal oxide layer 23 completely covers a high voltage device area HV2, a low voltage device area LV2, and a capacitor area PIP1. Subsequently, as shown in FIG. 2C, a high voltage well area 24 is formed in the high voltage device area HV2. The high voltage well area 24 is formed, for example, by an ion implantation process step, where N-type or P-type impurities are implanted into the area defined by a photomask 24′ in the form of accelerated ions, which is also well known in the art and not elaborated here. Next, as shown in FIG. 2D, a chemical vapor deposition (CVD) oxide layer 25 is formed completely covering the bottom thermal oxide layer 23. As shown in FIG. 2D, a polysilicon hard mask layer 26 is then formed completely covering the CVD oxide layer 25. In one embodiment, after forming the polysilicon hard mask layer 26, N-type or P-type ions are accelerated and implanted into the polysilicon hard mask layer 26, for example, by an ion implantation process step.

Continuing, as shown in FIGS. 2E and 2F, the polysilicon hard mask layer 26 is etched using a photomask 26′ to simultaneously form a high voltage polysilicon hard mask 26a in the high voltage device area HV2 and a first electrode plate 26b in the capacitor area. Then, as shown in FIG. 2G, for example, a wet etching process step is used to etch the CVD oxide layer 25, utilizing the high voltage polysilicon hard mask 26a and the first electrode plate 26b as etching barrier layers to simultaneously form a high voltage CVD oxide region 25a in the high voltage device area HV2 and a capacitor CVD oxide region 25b in the capacitor area PIP1. The formation of the high voltage CVD oxide region 25a, for example, may be performed by a deposition process step, which is also well known in the art and not elaborated here.

Continuing, as shown in FIG. 2H, a low voltage well area 27 is formed in the low voltage device area LV2. The low voltage well area 27 is formed, for example, by an ion implantation process step, where N-type or P-type impurities penetrate the sacrificial layer formed by the bottom thermal oxide layer 23 and are implanted into the low voltage device area LV2 defined by a photomask 27′, using accelerated ions. Next, as shown in FIG. 2I, the bottom thermal oxide layer 23 is etched using the high voltage polysilicon hard mask 26a and the first electrode plate 26b as etching barriers, to simultaneously form a high voltage bottom thermal oxide region 23a in the high voltage device area HV2 and a capacitor bottom thermal oxide region 23b in the capacitor area PIP1. In one embodiment, for example, a wet etching process step is used to etch the bottom thermal oxide layer 23, such that the high voltage sidewall of the high voltage bottom thermal oxide region 23a and the capacitor sidewall of the capacitor bottom thermal oxide region 23b each have an inclined angle with respect to the upper surface of substrate 21.

Afterwards, as shown in FIG. 2J, a high voltage gate oxide layer 28c, 28a is formed on the substrate 21 in the high voltage device area HV2, and a low voltage gate oxide layer 29 is formed on substrate 21 in the low voltage device area LV2. As shown in FIG. 2J, when forming the high voltage gate oxide layer 28c, 28a or the low voltage gate oxide layer 29, a capacitor dielectric layer 28b is simultaneously formed, connected and fully covering the first electrode plate 26b. Subsequently, as shown in FIG. 2K, a gate polysilicon layer 30 is formed, connected and fully covering the high voltage gate oxide layers 28c, 28a, the low voltage gate oxide layer 29, and the capacitor dielectric layer 28b. In one embodiment, after forming the gate polysilicon layer 30, N-type or P-type ions are accelerated and implanted into the gate polysilicon layer 30, for example, by an ion implantation process step. Subsequently, as shown in FIGS. 2L and 2M, the gate polysilicon layer 30 is etched using a photomask 30′ to simultaneously form a high voltage gate 30a in the high voltage device area HV2, a low voltage gate 30b in the low voltage device area LV2, and a second electrode plate 30c in the capacitor area PIP1. As shown in FIG. 2M, the high voltage gate 30a is in direct contact with the high voltage polysilicon hard mask 26a. As shown in FIG. 2M, a high voltage body region 37 is formed in the high voltage well area 24 of the high voltage device area HV2, and the high voltage source (described later) is located within the high voltage body region 37.

As shown in FIG. 2N, subsequently, after forming the high voltage gate 30a, the low voltage gate 30b, and the second electrode plate 30c, two high voltage spacers 31a are formed corresponding and connected on either side of the high voltage gate 30a, and two low voltage spacers 31b are formed corresponding and connected on either side of the low voltage gate 30b. As shown in FIG. 2N, in one embodiment, after forming the high voltage gate 30a, the low voltage gate 30b, and the second electrode plate 30c, two capacitor spacers 31c are formed corresponding and connected on either side of the second electrode plate 30c. As shown in FIG. 2O, subsequently, a high voltage source 32a and a high voltage drain 33a are simultaneously formed in the high voltage device area HV2, and a low voltage source 32b and a low voltage drain 33b are formed in the low voltage device area LV2. Next, as shown in FIG. 2P, for example, using a silicidation metal process step, plural silicide metal layers 34 are simultaneously formed corresponding to the upper surfaces of the high voltage gate 30a, a high voltage source 32a, a high voltage drain 33a, a low voltage gate 30b, a low voltage source 32b, a low voltage drain 33b, the first electrode plate 26b, and the second electrode plate 30c. Subsequently, as shown in FIG. 2Q, an inter-layer dielectric (ILD) layer 35 is formed on the substrate 21, completely covering the high voltage gate 30a, the low voltage gate 30b, and the second electrode plate 30c. As shown in FIG. 2Q, plural electrical contact plugs 36 are then formed (for example, penetrating) in the ILD layer 35 to electrically connect the multiple silicide metal layers 34.

In summary, the present invention utilizes high voltage polysilicon hard masks and the first electrode plate to achieve two-stage inclined high voltage bottom thermal oxide regions and high voltage CVD oxide regions without additional photomasks, simultaneously forms a PIP capacitor, and avoids shallow trench isolation (STI) notching, while reducing thermal processes to prevent exceeding the thermal budget during integration.

The present invention has been described in considerable detail with reference to certain preferred embodiments thereof. It should be understood that the description is for illustrative purpose, not for limiting the broadest scope of the present invention. Those skilled in this art can readily conceive variations and modifications within the spirit of the present invention. The various embodiments described above are not limited to being used alone; two embodiments may be used in combination, or a part of one embodiment may be used in another embodiment. For example, other process steps or structures, such as a deep well region, may be added. For another example, the lithography process step is not limited to the mask technology but it can also include electron beam lithography, immersion lithography, etc. Therefore, in the same spirit of the present invention, those skilled in the art can think of various equivalent variations and various combinations, and there are many combinations thereof, and the description will not be repeated here. The scope of the present invention should include what are defined in the claims and the equivalents.

What is claimed is:

1. A manufacturing method of an integrated structure of a semiconductor integrated structure having high and low voltage devices and a capacitor, comprising:
forming a bottom thermal oxide layer on a substrate, wherein the bottom thermal oxide layer completely covers a high voltage device area, a low voltage device area, and a capacitor area of the substrate;
forming a high voltage well in the substrate of the high voltage device area;
forming a chemical vapor deposition (CVD) oxide layer that completely covers the bottom thermal oxide layer;
forming a polysilicon hard mask layer that completely covers the CVD oxide layer;
etching the polysilicon hard mask layer to simultaneously form a high voltage polysilicon hard mask in the high voltage device area and a first electrode plate in the capacitor area;
etching the CVD oxide layer using the high voltage polysilicon hard mask and the first electrode plate as etching barriers to simultaneously form a high voltage CVD oxide region in the high voltage device area and a capacitor CVD oxide region in the capacitor area;
forming a low voltage well in the substrate of the low voltage device area;
etching the bottom thermal oxide layer using the high voltage polysilicon hard mask and the first electrode plate as etching barriers to simultaneously form a high voltage bottom thermal oxide region in the high voltage device area and a bottom thermal oxide region in the capacitor area;
forming a high voltage gate oxide layer over the high voltage device area on the substrate;
forming a low voltage gate oxide layer over the low voltage device area on the substrate;
when forming the high voltage gate oxide layer or the low voltage gate oxide layer, simultaneously forming a capacitor dielectric layer, connected and fully covering the first electrode plate;
forming a gate polysilicon layer, connected and fully covering the high voltage gate oxide layer, the low voltage gate oxide layer, and the capacitor dielectric layer; and
etching the gate polysilicon layer to simultaneously form a high voltage gate in the high voltage device area, a low voltage gate in the low voltage device area, and a second electrode plate in the capacitor area.

2. The manufacturing method of claim 1, wherein the step of forming the low voltage well in the substrate of the low voltage device area includes: using an ion implantation process step, with the bottom thermal oxide layer serving as a sacrificial layer, and accelerating ions to penetrate the sacrificial layer to implant into the low voltage device area to form the low voltage well.

3. The manufacturing method of claim 1, wherein the step of etching the CVD oxide layer using the high voltage polysilicon hard mask and the first electrode plate as etching barriers to simultaneously form the high voltage CVD oxide region in the high voltage device area and the capacitor CVD oxide region in the capacitor area includes: using a wet etching process step to etch the CVD oxide layer.

4. The manufacturing method of claim 1, wherein the step of etching the bottom thermal oxide layer using the high voltage polysilicon hard mask and the first electrode plate as etching barriers to simultaneously form the high voltage bottom thermal oxide region in the high voltage device area and the bottom thermal oxide region in the capacitor area includes: using a wet etching process step to etch the bottom thermal oxide layer, such that the high voltage side wall of the high voltage bottom thermal oxide region and the capacitor side wall of the bottom thermal oxide region each have an inclined angle with respect to the upper surface of the substrate.

5. The manufacturing method of claim 1, further comprising: after forming the polysilicon hard mask layer, using an ion implantation process step to accelerate N-type or P-type ions to implant into the polysilicon hard mask layer.

6. The manufacturing method of claim 1, further comprising: after forming the gate polysilicon layer, using an ion implantation process step to accelerate N-type or P-type ions to implant into the gate polysilicon layer.

7. The manufacturing method of claim 1, wherein the high voltage gate is in direct contact with the high voltage polysilicon hard mask.

8. The manufacturing method of claim 1, further comprising: after forming the high voltage gate, the low voltage gate, and the second electrode plate, forming two high voltage spacers corresponding to and connected on either side of the high voltage gate, and two low voltage spacers corresponding to and connected on either side of the low voltage gate.

9. The manufacturing method of claim 8, further comprising: after forming the high voltage gate, the low voltage gate, and the second electrode plate, forming two capacitor spacers corresponding to and connected on either side of the second electrode plate.

10. The manufacturing method of claim 1, further comprising: simultaneously forming a high voltage source and a high voltage drain in the high voltage device area, and a low voltage source and a low voltage drain in the low voltage device area.

11. The manufacturing method of claim 10, further comprising: using a silicidation metal process step to simultaneously form a plurality of silicide metal layers corresponding to the upper surfaces of the high voltage gate, the high voltage source, the high voltage drain, the low voltage gate, the low voltage source, the low voltage drain, the first electrode plate, and the second electrode plate.

12. The manufacturing method of claim 1, further comprising: forming an inter-layer dielectric (ILD) layer on the substrate, completely covering the high voltage gate, the low voltage gate, and the second electrode plate.

13. The manufacturing method of claim 12, further comprising: forming a plurality of electrical contact plugs in the ILD layer, electrically connecting the multiple silicide metal layers.

14. The manufacturing method of claim 1, further comprising: forming a high voltage body region in the high voltage well of the high voltage device area, wherein the high voltage source is located in the high voltage body region.
